(19) United States
(12) Patent Application Publication
(10) Pub. No.: US 2012/0026270 A1
(43) Pub. Date: Feb. 2, 2012

(54) ORGANIC EL DEVICE, METHOD OF MANUFACTURING THE SAME AND PRINTER

(75) Inventors: Shiro Sumita, Kanazwa-Shi (JP); Motonobu Aoki, Maikata-Shi (JP); Masuyuki Oota, Hakusan-Shi (JP)

(73) Assignee: Toshiba Mobile Display Co., Ltd., Saitama-ken (JP)

(21) Appl. No.: 13/149,825

(22) Filed: May 31, 2011

(30) Foreign Application Priority Data
Jul. 27, 2010 (JP) JP2010-168353

(51) Int. Cl. B41J 2/435; H01L 33/00; H01L 21/00

(52) U.S. Cl. 347/224; 257/99; 438/26; 257/E33.056

(57) ABSTRACT

According to one embodiment, an organic EL device includes a first substrate, a second substrate, an adhesive agent, and a drying agent. An organic EL element is formed on the first substrate. The second substrate has a first surface facing the first substrate and a second surface on an opposite side from the first surface. A concave portion having a bottom portion and a sidewall portion is formed on the first surface. The adhesive agent is surrounding the organic EL element. The adhesive agent is configured to join the first substrate and the second substrate to each other. The drying agent is applied to at least a part of the bottom portion and the sidewall portion of the concave portion.

### CROSS REFERENCE TO RELATED APPLICATIONS

This application is based upon and claims the benefit of priority from the prior Japanese Patent Application No. 2010-168353, filed on Jul. 27, 2010, the entire contents of which are incorporated herein by reference.

### FIELD

Embodiments described herein relate generally to an organic EL device, a method of manufacturing the same and a printer.

### BACKGROUND

An organic EL device is formed by joining a first substrate having organic EL elements formed thereon to a second substrate facing the first substrate. Organic EL elements are degraded due to moisture. Particularly, electron transport layers in organic EL elements are extremely poor in resistance to moisture, and are degraded when moisture exists, resulting in display defects. Therefore, there has been a suggested technique by which a concave portion is formed in the second substrate, and a drying agent is applied to the concave portion.

However, it is difficult to form a rectangular concave portion through a conventional manufacturing process, and a concave portion normally has a tapered shape. In a case where a sheet-shape drying agent is used, the drying agent cannot be stably attached to a tapered area.

In recent years, organic EL devices have been used for various applications such as display systems and printer heads. The aspect ratio in organic EL devices for display systems is 3:4 or 9:16, for example. Since the ratio of the short-side (the width) to the long-side is relatively high, a sufficient width can be secured for the bottom of the above described concave portion, and a drying agent can be readily applied to the concave portion. However, organic EL devices for printer heads have longer and thinner shapes, and a sufficient width cannot be secured for the bottom portion of the concave portion. As described above, a drying agent cannot be stably applied to a tapered region. Therefore, the amount of the drying agent to be applied becomes smaller, and the moisture in organic EL elements cannot be sufficiently absorbed.

### BRIEF DESCRIPTION OF THE DRAWINGS

FIG. 1 is a short-side cross-sectional view of an organic EL device 100 according to a first embodiment.

FIG. 2 is a plan view of the organic EL device 100 of FIG. 1.

FIG. 3 is a process chart showing steps of manufacturing the organic EL device 100 shown in FIGS. 1 and 2.

FIG. 4 is a short-side cross-sectional view of an organic EL device 101 as a modification of the first embodiment.

FIG. 5 is a plan view of the organic EL device 101 of FIG. 4.

FIG. 6 is a cross-sectional view illustrating the situation where the first substrate 1 and the second substrate 3 are bonded to each other in step S6 of FIG. 3.

FIG. 7 is a graph showing the relationship between the distance “H” and the pressure P0.

FIG. 8 is a table showing the thicknesses “d” of the drying agents 4 and the number of defects in the organic EL devices 101a through 101e.

FIG. 9 is a table showing the conditions for manufacturing the organic EL devices 101f through 101k and the number of defects therein.

FIG. 10 is a plan view of an organic EL device 102 according to the second embodiment.

FIG. 11 is a cross-sectional view of the organic EL device 102, taken along the line C-C′ of FIG. 10.

FIG. 12 is a cross-sectional view of the organic EL device 102, taken along the line D-D′ of FIG. 10.

FIG. 13 is a plan view of an organic EL device 103 as a modification of the second embodiment.

FIG. 14 is a cross-sectional view of the organic EL device 103, taken along the line E-E′ of FIG. 13.

FIG. 15 is a schematic block diagram showing a printer using an organic EL element.

### DETAILED DESCRIPTION

In general, according to one embodiment, an organic EL device includes a first substrate, a second substrate, an adhesive agent, and a drying agent. An organic EL element is formed on the first substrate. The second substrate has a first surface facing the first substrate and a second surface on an opposite side from the first surface. A concave portion having a bottom portion and a sidewall portion is formed on the first surface. The adhesive agent is surrounding the organic EL element. The adhesive agent is configured to join the first substrate and the second substrate to each other. The drying agent is applied to at least a part of the bottom portion and the sidewall portion of the concave portion.

A distance “H” between a surface of the drying agent and the first surface of the second substrate is within a range defined by a following equation:

(A1+A2)*(h0*P0−h1)/{A1*(1−P0)}≦H<D/2

where “A1” represents an area of a region where the concave portion is formed, “A2” represents an area obtained by subtracting the area of the region where the concave portion is formed from an area inside the adhesive agent in the second substrate, “h0” and “P0” represent a height of the adhesive agent and a pressure in a surrounding area of the organic EL element before the first substrate and the second substrate are pressurized and joined to each other respectively, “h1” and “P1” represent a height of the adhesive agent and a pressure in the surrounding area of the organic EL element after the first substrate and the second substrate are pressurized and joined to each other respectively, “D” represents a thickness of the second substrate, “A1” is greater than 0, and “P0” is lower than 1.

The following is a detailed description of embodiments of organic EL devices, a method of manufacturing the organic EL devices and a printer, with reference to the accompanying drawings.

### First Embodiment

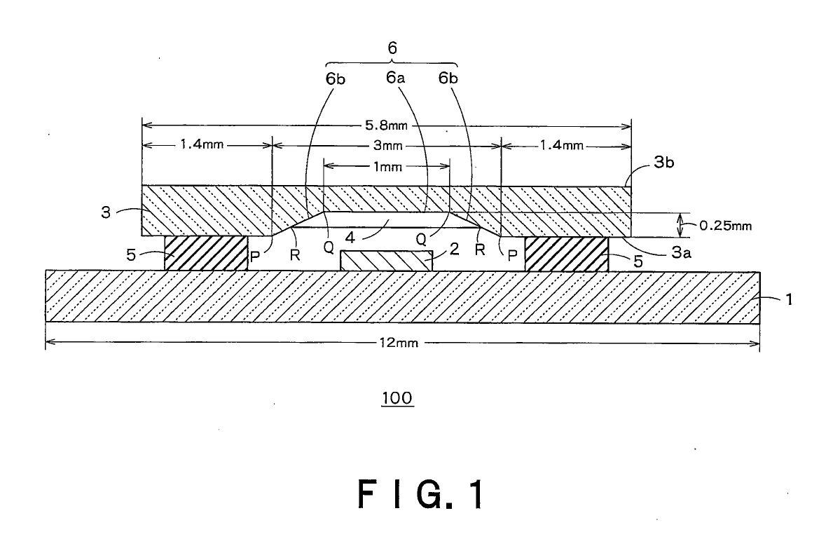

FIG. 1 is a short-side cross-sectional view of an organic EL device 100 according to a first embodiment. The organic EL device 100 of FIG. 1 includes a first substrate 1 having organic EL elements 2 formed thereon, a second substrate 3 arranged to facing the first substrate 1, a drying agent 4 applied to a concave portion of the second substrate 3, and an adhesive agent 5 bonding the first substrate 1 and the second substrate 3 to each other. This organic EL device 100 is of a bottom emission type where the light emitted by the organic EL elements 2 is taken out from the side of the first substrate 1, and is used as a printer head for laser printers, for example.

The first substrate 1 is a glass substrate having a thickness of 12 mm, for example. One or more groups of organic EL elements 2 are formed on the first substrate 1.

Although not shown in FIG. 1, each of the organic EL elements 2 includes an anode, a hole transport layer, a light emitting layer, an electron transport layer, an electron injection layer, and a cathode, for example. The hole transport layer is an α-NAD layer having a thickness of 200 nm, for example. The light emitting layer that also serves as the electron transport layer is an Alq₃ layer having a thickness of 50 nm in thickness, for example. The electron injection layer is a LiF layer having a thickness of 1 nm, for example. The cathode is an aluminum layer having a thickness of 150 nm in thickness, for example. When holes injected from the anode into the light emitting layer via the hole transport layer are recombined with electrons injected from the cathode into the light emitting layer via the electron transport layer, light is emitted in a color that depends on the kinds of impurities contained in the light emitting layer.

The second substrate 3 is a glass substrate having a width of 5.8 mm, for example, and is positioned to face the first substrate 1 with a distance kept therebetween. The second substrate 3 includes a first surface 3a that faces the first substrate 1, and a second surface 3b located on the opposite side from the first surface 3a. A concave portion 6 is formed on the first surface 3a. The concave portion 6 includes a bottom portion 6a that is substantially parallel to the first surface 3a, and sidewall portions 6b that slope from the bottom portion 6a to the first surface 3a. The width of the bottom portion 6a is 1 mm, for example. The width of the opening of the concave portion 6 is equal to the value obtained by adding the widths of the sidewall portions 6b to the width of the bottom portion 6a. Therefore, the width of the opening of the concave portion 6 is greater than 1 mm, or may be 3 mm, for example. If the concave portion 6 is too deep, the strength of the second substrate 3 becomes lower, and therefore, the concave portion 6 needs to have a depth smaller than a half the depth of the second substrate 3. For example, when the thickness of the second substrate 3 is 0.6 mm, the depth of the concave portion 6 needs to be smaller than 0.3 mm, and may be 0.25 mm, for example. It should be noted that the bottom portion 6a is not necessarily flat, and may be curved, for example.

The drying agent 4 is applied to the concave portion 6 of the second substrate 3. More specifically, the drying agent 4 is applied to the bottom portion 6a and at least a part of the sidewall portions 6b of the concave portion 6. The drying agent 4 absorbs moisture in the organic EL device 100, and protects the organic EL elements 2. The drying agent 4 contains aluminosilicate-based zeolite as a main component, for example.

The adhesive agent 5 may be an UV-curable epoxy resin, for example. The adhesive agent 5 is interposed between the first substrate 1 and the second substrate 3 so as to surround the organic EL elements 2. The adhesive agent 5 bonds the first substrate 1 and the second substrate 3 to each other.

When the first substrate 1 and the second substrate 3 are bonded to each other with the adhesive agent 5, pressure needs to be applied onto both of the substrates, and the width of the adhesive agent 5 becomes greater accordingly. With the width of the adhesive agent 5 after the pressurizing being taken into consideration, each region extending from the lines P on which the first surface 3a and the sidewall portions 6b meet to the edge of the second substrate 3 needs to be a region having a width of 1.4 mm, for example. Since such a region exists on either side of the concave portion 6, a total width of 2.8 mm is required as the width of the adhesive agent 5.

When a sheet-shape drying agent is used, the width of the drying agent 4 cannot be made much smaller due to process limitations, and the minimum value of the width of the bottom portion 6a of the concave portion 6 is naturally limited. With the moisture-absorption properties of the drying agent 4 being taken into consideration, the drying agent 4 needs to have a reasonable width. In view of these, the width of the bottom portion 6a needs to be at least approximately 3 mm. Since the width of each of the sidewall portions 6b is approximately 1 mm, the width of the opening portion of the concave portion 6 needs to be approximately 5 mm. As described above, the width of the adhesive agent 5 needs to be approximately 2.8 mm in total. Therefore, the width of the second substrate 3 can be reduced only to approximately 7.8 mm.

In this embodiment, on the other hand, the fluid drying agent 4, instead of a sheet-shape drying agent, is applied to the concave portion 6, and is cured afterward. Accordingly, the drying agent 4 can be stably applied not only to the bottom portion 6a but also to at least a part of the sidewall portions 6b. In this manner, the width of the bottom portion 6a can be reduced to as small as approximately 1 mm, and the width of the opening portion can be reduced to as small as approximately 3 mm in this embodiment. Accordingly, the organic EL device 100 in which the width of the second substrate 3 is as small as 5.8 mm can be realized, without degradation of the moisture-absorption properties. The value of the width is an example value based on the performance of the drying agent 4. If a drying agent having higher absorption-moisture properties than the above is used, the width of the organic EL device 100 can be made even smaller.

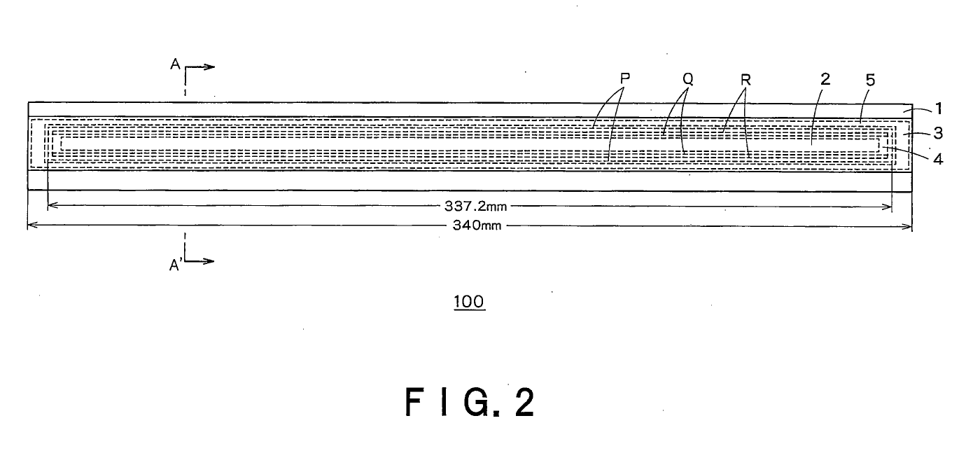

FIG. 2 is a plan view of the organic EL device 100 of FIG. 1. FIG. 1 corresponds to a cross-sectional view of the organic EL device 100, taken along the line A-A′ of FIG. 2. In FIG. 2, the line on which the first surface 3a of the second substrate 3 meets the sidewall portions 6b is represented by the broken line P, the line on which the bottom portion 6a of the concave portion 6 meets the sidewall portions 6b is represented by a broken line Q, and the rim of the drying agent 4 is represented by a broken line R. As shown in the drawing, the length of each of the first substrate 1 and the second substrate 3 is 340 mm, for example. This length is set to cope with a case where a printer head capable of printing on “A4” size paper sheets with the organic EL device 100 is manufactured. The length of the concave portion 6 in the longitudinal direction in this case is 337.2 mm, for example.

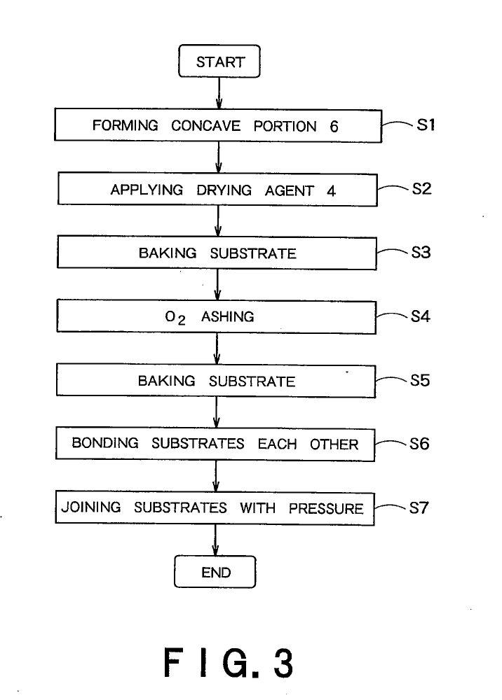

FIG. 3 is a process chart showing steps of manufacturing the organic EL device 100 shown in FIGS. 1 and 2. Firstly, the concave portion 6 is formed in the second substrate 3 by a sandblasting technique (step S1). The fluid drying agent 4 is then applied to the concave portion 6 (step S2). More specifically, zeolite, which is the material of the drying agent 4, is dissolved in an organic solvent such as methanol or ethanol, and a viscosity modifier is dissolved in the solvent to control the viscosity of the drying agent 4 as needed. The drying agent 4 in such a fluid state is applied to the concave portion 6 of the second substrate 3 with a dispenser system.

The second substrate 3 is baked at 300° C. for 15 hours, for example (step S3). Through this step, the solvent, moisture, and viscosity modifier in the drying agent 4 are removed, and the drying agent 4 is cured. The thickness of the cured drying agent 4 is represented by d. The upper limit and lower limit of the thickness “d” of the drying agent 4 will be described later. When substrate baking is performed, the components of the drying agent 4 partially volatilize and adhere to the inner surface of the second substrate 3. If the adherent matter, particularly, the silane-based material, remains on the inner surface of the second substrate 3, the adhesion strength of the adhesive agent 5 becomes lower.

Therefore, O₂ ashing is performed on the second substrate 3 for 150 second, for example (step S4). Through this step, the adherent matter remaining on the second substrate 3 is removed, and the adhesion strength of the adhesive agent 5 can be improved. Oxygen and moisture are generated through the O₂ ashing. However, if the oxygen and moisture remain, the organic EL elements 2 are degraded.

In view of this, the second substrate 3 is further baked at 230° C. for 10 to 20 minutes, for example (step S5). Through this step, oxygen and moisture are removed, and degradation of the organic EL elements 2 can be restrained. If the substrate baking is performed for too long a time, the components of the drying agent 4 partially volatilize again. Therefore, the substrate baking is preferably performed in a short period of time. The steps S3 through S5 are preferably performed in vacuum or in a nitrogen atmosphere where oxygen concentration and water concentration is 1 ppm or lower, except for the transferring procedures.

The first substrate 1 having the organic EL elements 2 formed thereon in advance is bonded to the second substrate 3 under reduced pressure through the UV-curable adhesive agent 5 provided surrounding the organic EL elements 2 (step S6). The adhesive agent 5 is then exposed to ultraviolet rays while being pressurized, so that the first substrate 1 and the second substrate 2 are joined to each other (step S7). In this manner, the organic EL device 100 shown in FIGS. 1 and 2 is formed. It should be noted that a thermosetting adhesive agent may be used as the adhesive agent 5, and the adhesive agent is heated to join the first substrate 1 and the second substrate 3 to each other.

As a modification, in step S1, a concave portion may be formed not by a sandblasting technique but be formed by chemical etching with the use of a chemical solution such as a hydrofluoric acid. In that case, a concave portion 6′ having a different shape from the concave portion 6 of FIG. 2 is formed.

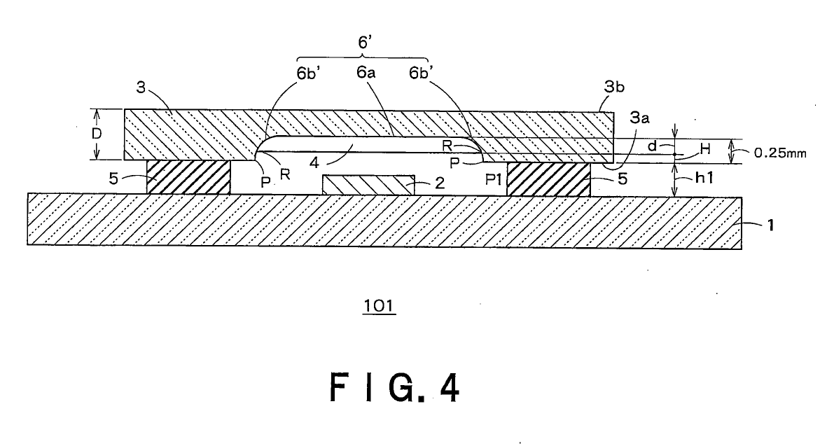

FIG. 4 is a short-side cross-sectional view of an organic EL device 101 as a modification of the first embodiment. The concave portion 6′ of the second substrate 3 includes the bottom portion 6a that is substantially parallel to the first surface 1a, and sidewall portions 6b′ that are curved toward the first surface 3a. The drying agent 4 is applied to the bottom portion 6a and at least a part of the sidewall portions 6b′. Since the sidewall portions 6b′ are curved in the organic EL device 101, a higher strength than that of the organic EL device 100 can be achieved, and the total amount of the drying agent 4 can be increased.

Meanwhile, there are the upper limit and the lower limit of the thickness “d” of the drying agent 4 to be applied to the concave portion 6′. First, in order to determine the upper limit, respective parameters are defined as follows.

In FIG. 4, h1 represents the height of the adhesive agent 5 where the first substrate 1 and the second substrate 3 are pressurized and joined to each other, “P1” represents the pressure in the surrounding area of the organic EL elements 2, “d” represents the thickness of the drying agent 4, “H” represents the distance between the first surface 3a and the surface of the drying agent 4, and “D” represents the thickness of the second substrate 3.

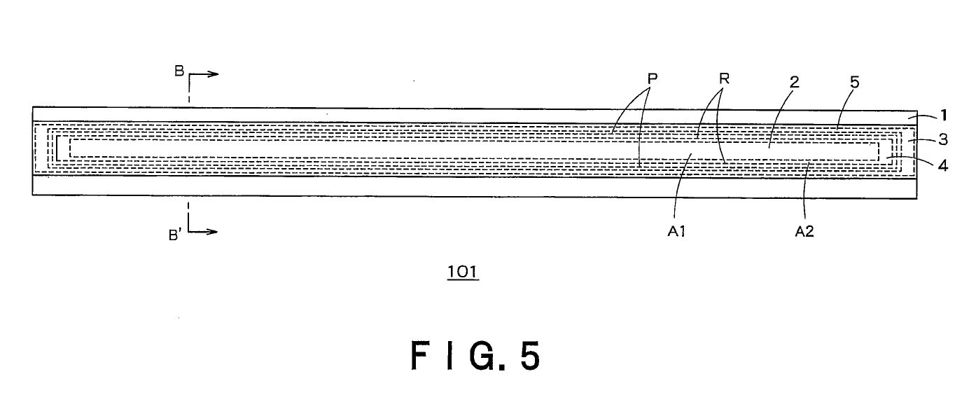

FIG. 5 is a plan view of the organic EL device 101 of FIG. 4. FIG. 4 corresponds to a cross-sectional view of the organic EL device 101, taken along the line B-B′ of FIG. 5. The broken lines P and R represent the same lines as those in FIG. 2. “A1” represents the area of the region in which the concave portion 6′ of the second substrate 3 is formed inside the adhesive agent 5 (disregarding the area inside the broken line P and the areas of the sidewall portions 6b′ to which the drying agent 4 is not applied), and “A2” represents the area obtained by subtracting the area of the region in which the concave portion 6′ is not formed, that is, the area inside the adhesive agent 5 from the area A1.

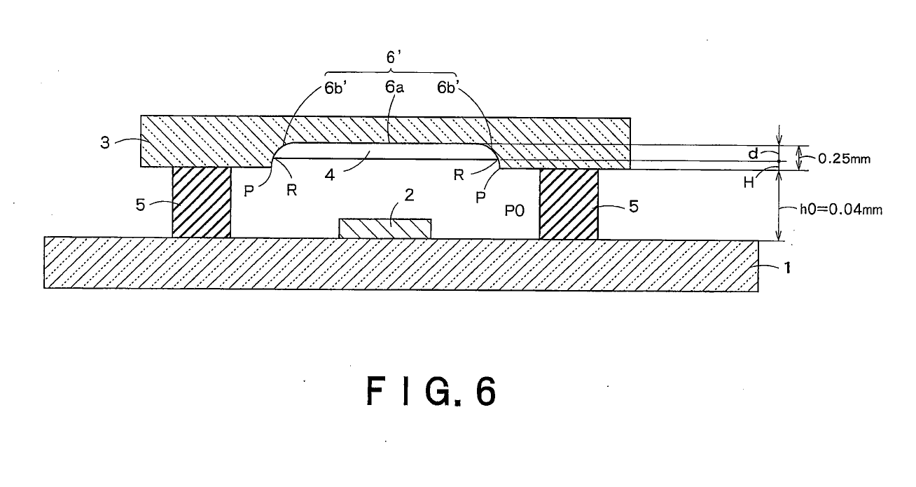

FIG. 6 is a cross-sectional view illustrating the situation where the first substrate 1 and the second substrate 3 are bonded to each other in step S6 of FIG. 3. In FIG. 6, “h0” represents the height of the adhesive agent 5 in the situation illustrated in FIG. 6, that is, in the situation before joining through pressurization, and “P0” represents the pressure in the surrounding area of the organic EL elements 2.

The organic EL device 101 of FIG. 4 is formed by pressurizing the first substrate 1 and the second substrate 3 shown in FIG. 6, and joining those substrates to each other with the adhesive agent 5. Therefore, the height h1 is lower than the height h0, and the pressure “P1” is higher than the pressure P0. If the pressure “P1” is higher than atmospheric pressure (1 atm), the adhesive agent 5 is damaged. Therefore, the pressure “P1” needs to be equal to or lower than atmospheric pressure. The lower limit of the distance “H” between the first surface 3a and the surface of the drying agent 4 is determined from those conditions, and, as a result, the upper limit of the thickness “d” of the drying agent 4 is determined.

In the following, the determination of parameters will be described in more detail. The product of pressure and volume is constant between FIG. 4 illustrating the situation prior to the pressurization and FIG. 6 illustrating the situation after the pressurization, according to Boyle's law. Therefore, the following equation (1) is established:

P0*{(H+h0)*A1+h0*A2}=P1*{(H+h1)*A1+h1*A2} (1)

Furthermore, the pressure “P1” needs to be equal to or lower than atmospheric pressure, 1 atm. Therefore, the following equation (2) is established:

P1≦1 (2)

According to the above equations (1) and (2), the following equation (3) is established:

H≧(A1+A2)*(h0*P0−h1)/{A1*(1−P0)} (3)

Since the drying agent 4 is provided in the concave portion 6′, the area “A1” is greater than 0 in the above equation (3). Additionally, since the first substrate 1 and the second substrate 3 are bonded to each other under reduced pressure before joining through pressurization, the pressure “P0” is lower than 1. Further, since the depth of the concave portion 6′ needs to be smaller than half the thickness of the second substrate 3 as described above, the distance “H” is determined by the following equation (4), where “D” represents the thickness of the second substrate 3:

(A1+A2)*(h0*P0−h1)/{A1*(1−P0)}≦H<D/2 (4)

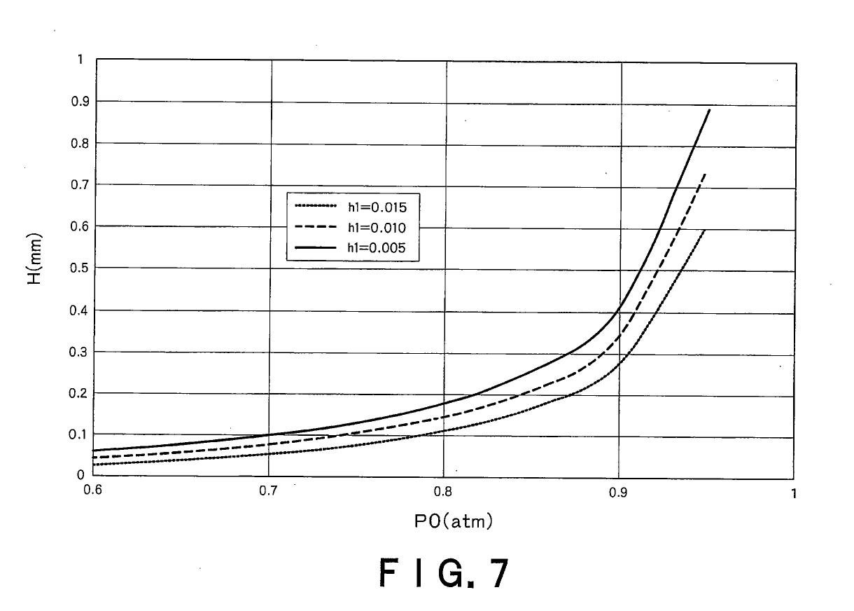

FIG. 7 is a graph showing the relationship between the distance “H” and the pressure “P0”. The graph shown in FIG. 7 is obtained by calculations in the following assumption: (A1+A2)/A1 is 1.34, “h0” is 0.04 mm, and the height h1 of the adhesive agent 5 is 0.015 mm, 0.010 mm and 0.005 mm. In a conventional manufacturing apparatus, the pressure “P0” is approximately 0.7 to atm. Therefore, the lower limit of the distance “H” is approximately 0.1 mm, according to the graph shown in FIG. 7.

Where “H0” represents the depth of the concave portion 6′, the thickness “d” of the drying agent 4 needs to satisfy the following equation (5):

d=H0−H≦H0−(A1+A2)*(h0*P0−h1)/{A1*(P0−1)} (5)

When the depth “H0” of the concave portion 6′ is 0.25 mm, the upper limit of the thickness “d” of the drying agent 4 is 0.25−0.1=0.15 mm.

The difference between the organic EL device 100 of FIG. 1 and the organic EL device 101 of FIG. 4 is only in whether the sidewall portions 6b are sloped or curved. Therefore, in the organic EL device 100, the upper limit of the thickness “d” of the drying agent 4 is also determined by the above equation (5), as in the organic EL device 101.

Meanwhile, the lower limit of the thickness “d” of the drying agent 4 is determined in the following manner. If the amount of the drying agent 4 is small, the moisture that is not absorbed by the drying agent 4 and remains in the organic EL device 100 or 101 degrade the organic EL elements 2. Therefore, the lower limit of the thickness “d” of the drying agent 4 is determined by the amount of the drying agent 4 necessary for absorbing moisture and protecting the organic EL elements 2.

This lower limit can be experimentally determined, for example. An example of the results of a comparison experiment in which organic EL devices 101 having the drying agent 4 with different thicknesses “d” will be described below. The amount of the drying agent 4 to be applied was varied, and five difference types of organic EL devices 101a through 101e were manufactured. The number of the organic EL devices of each type was thirty. The thickness “d” of the drying agent 4 of one of the organic EL devices of each type was measured. The number of unstuck defects in each of fourteen organic EL devices of each type was counted, and the number of dark spot defects in each of the remaining fifteen organic EL devices of each type was counted. The depth of the concave portion 6′ was 0.25 mm.

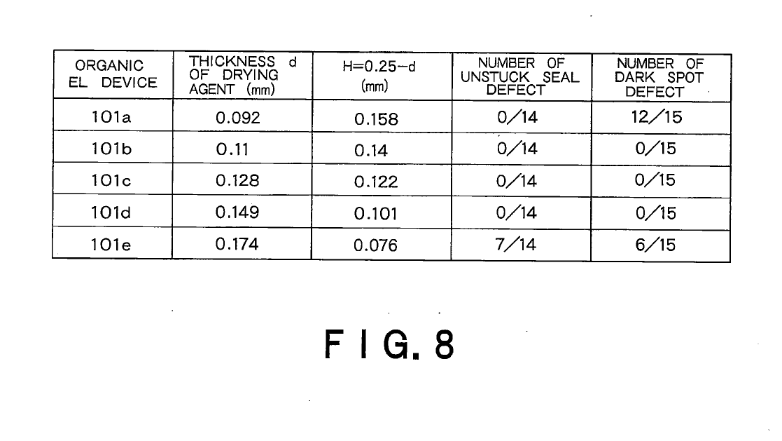

FIG. 8 is a table showing the thicknesses “d” of the drying agents 4 and the number of defects in the organic EL devices 101a through 101e. As shown in FIG. 8, in the organic EL device 101a having the drying agent 4 with the thickness “d” of 0.092 mm, unstuck defects did not occur, but twelve dark spot defects occurred. In the organic EL devices 101b through 101d having the drying agents 4 with the thicknesses “d” of 0.11 to 0.149 mm, neither unstuck defects nor dark spot defects occurred. In the organic EL device 101e having the drying agent 4 with the thickness “d” of 0.174 mm, seven unstuck defects and six dark spot defects occurred.

Since the thickness “d” of the drying agent 4 in the organic EL device 101a is as small as 0.092 mm, moisture in the organic EL device 101a cannot be sufficiently absorbed. As a result, there are a number of dark spot defects. In the organic EL device 101b, on the other hand, the thickness “d” of the drying agent 4 is 0.11 mm, and there are no dark spot defects. Therefore, the lower limit of the thickness “d” of the drying agent 4 should be set at 0.11 mm.

In the organic EL device 101d having the drying agent 4 with the thickness “d” of 0.149 mm, there are no unstuck defects. In the organic EL device 101e having the drying agent 4 with the thickness “d” of 0.174 mm, however, there are unstuck defects. This is because, as the thickness “d” of the drying agent 4 is as great as 0.174 mm, the volume inside the organic EL device 101e is small, and the pressure inside the organic EL device 101e is higher than atmospheric pressure. As described above, the upper limit of the thickness “d” of the drying agent 4 according to the equation (5) is 0.15 mm, which matches the experiment results.

In view of that, the thickness “d” of the drying agent 4 is made equal to or greater than the lower limit based on the experiment results shown in FIG. 8, and is also made equal to or lower than the upper limit according to the equation (5). In this manner, an appropriate amount of drying agent 4 can be provided so that the moisture in the organic EL device 101 can be sufficiently absorbed, and the pressure in the surrounding area of the organic EL elements 2 does not become too high.

To confirm the effects of the O₂ ashing (step S4 of FIG. 3) and the second substrate baking (step S5), a comparison experiment was carried out by manufacturing organic EL devices 101f through 101k under different manufacturing conditions. In this experiment, six different types of the organic EL devices 101f through 101k were manufactured, using second substrates 3 of 400×500 mm each having a concave portion 6′ formed by chemical etching. The number of organic EL devices of each of the six types was thirty.

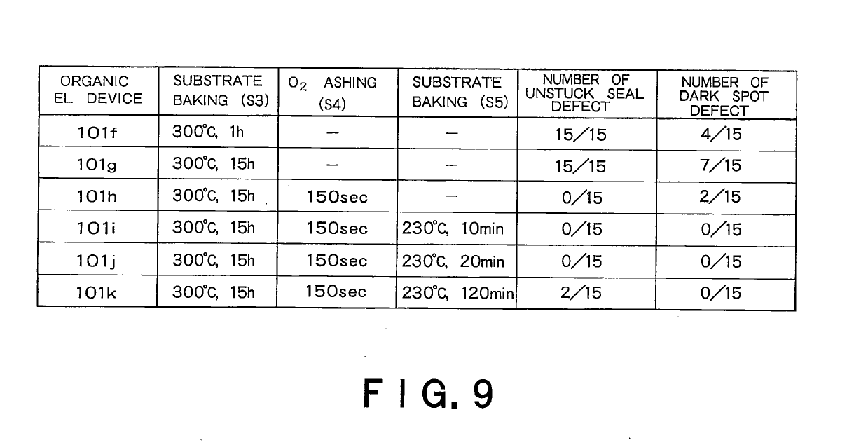

FIG. 9 is a table showing the conditions for manufacturing the organic EL devices 101f through 101k and the number of defects in the organic EL devices 101a through 101f. For the organic EL devices 101f and 101g, substrate baking (step S3 of FIG. 3) was performed at 300° C. for one hour and 15 hours, respectively, and the O₂ ashing (step S4) and the second substrate baking (step S5) were not performed. For the organic EL device 101h, the substrate baking was performed at 300° C. for 15 hours, and the O₂ ashing was performed for 150 seconds. However, the second substrate baking was not performed. For the organic EL devices 101i, 101j, and 101k, the substrate baking was performed at 300° C. for 15 hours, and O₂ ashing was then performed for 150 seconds. Further, the second substrate baking was performed at 230° C. for 10 minutes, 20 minutes, and 120 minutes, respectively.

Among the thirty organic EL devices of each type of the organic EL devices 101f through 101k, the number of unstuck defects was counted in each of fifteen organic EL devices, and the number of dark spot defects was counted in each of the remaining fifteen organic EL devices.

As shown in FIG. 9, there are unstuck defects in all the organic EL devices 101f and 101g in which the O₂ ashing (step S4) was not performed. This is because the components of the volatilized drying agent 4 partially remain on the second substrate 3 due to the first substrate baking, and the adhesion strength of the adhesive agent 5 becomes lower. In each of the organic EL devices 101h through 101k in which the O₂ ashing was performed, on the other hand, the number of unstuck defects is restrained. This is because the adherent matter is removed from the second substrate 3 by the O₂ ashing, and the adhesion strength of the adhesive agent 5 improves.

There are dark spot defects in two of the organic EL device 101h in which the second substrate baking (step S5) was not performed. This is because the oxygen and moisture generated by the O₂ ashing remain and degrade the organic EL elements 2. Contrarily, in the organic EL devices 101i through 101k in which the second substrate baking was performed, there are no dark spot defects. This is because the oxygen and moisture are removed by the second substrate baking, and degradation of the organic EL devices 101i through 101k can be restrained.

Further, there are no unstuck defects in the organic EL devices 101i and 101j in which the second substrate baking was performed for 10 to 20 minutes. However, there are unstuck defects in the organic EL device 101k in which the second substrate baking was performed for 120 minutes. This is because, if the second substrate baking is performed for too long time, the drying agent 4 partially volatilizes and remains on the second substrate 3.

As described above, after the drying agent 4 is cured by the first substrate baking, the O₂ ashing is performed, and the second substrate baking is performed for an appropriate period of time. In this manner, manufacturing defects can be prevented.

As described above, in the first embodiment, the fluid drying agent 4 is used. Accordingly, the drying agent 4 can be applied not only to the bottom portion 6a of the concave portion 6 or 6′ formed in the second substrate 3 but also to the sidewall portions 6b or 6b′. With this arrangement, a wide region can be secured for the drying agent 4 even if the concave portion 6 is made narrower, and the moisture in the organic EL elements can be sufficiently absorbed. Also, since the fluid drying agent 4 is used, the amount of the drying agent 4 can be readily controlled so that the pressure inside the organic EL device does not become too high. As a result, even if the organic EL device 100 is made narrower, degradation and display defects hardly occur. Furthermore, unstuck defects can be restrained, as the O₂ ashing is performed after the fluid drying agent 4 is cured by substrate baking. Also, dark spot defects can be restrained, as substrate baking is performed for a short period of time after the O₂ ashing.

### Second Embodiment

In the above described first embodiment, the organic EL device 100 is an organic EL device of the bottom emission type where the light emitted by the organic EL elements 2 is taken out from the side of the first substrate 1. On the other hand, a second embodiment described below concerns an organic EL device of a top emission type where the light is taken out from the side of the second substrate 3.

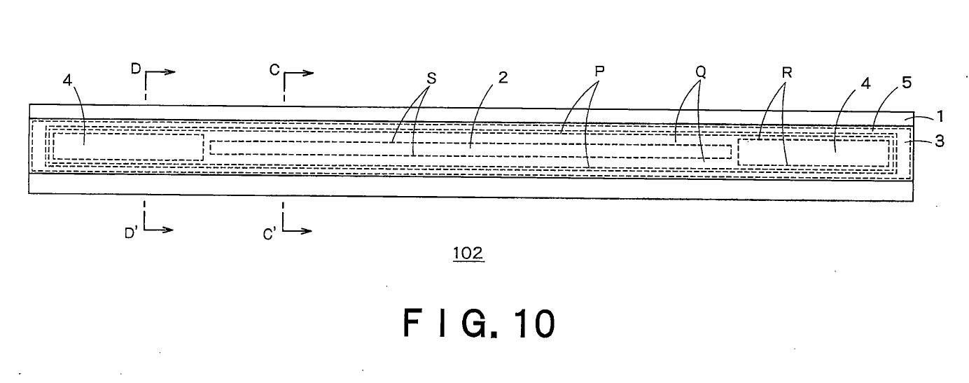

FIG. 10 is a plan view of an organic EL device 102 according to the second embodiment. In FIG. 10, the same components as those shown in FIG. 2 are denoted by the same reference numerals as those used in FIG. 2, and the different aspects between the two embodiments will be mainly described below.

In the concave portion 6 formed in the second substrate 3 of the organic EL device 102, the drying agent 4 is not applied to the bottom portion 6a and the sidewall portions 6b located above the organic EL elements 2. The drying agent 4 is applied only to the concave portion 6 located outside the organic EL elements 2 in the longitudinal direction. With this arrangement, the light emitted by the organic EL elements 2 is not shielded by the drying agent 4, and can be taken out from the organic EL device 102.

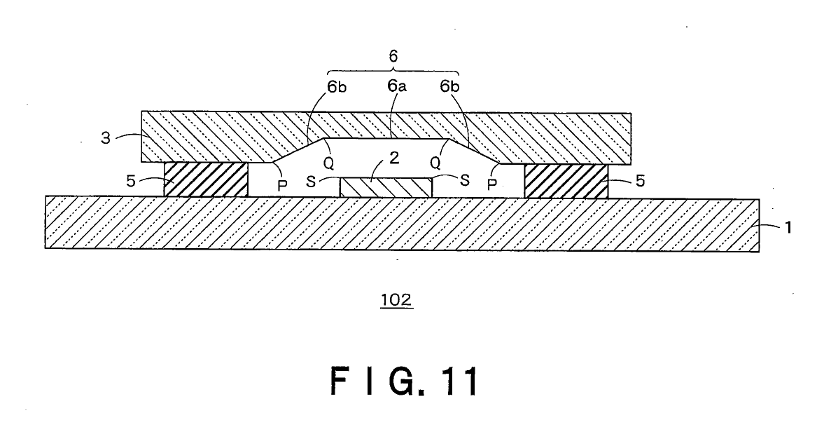

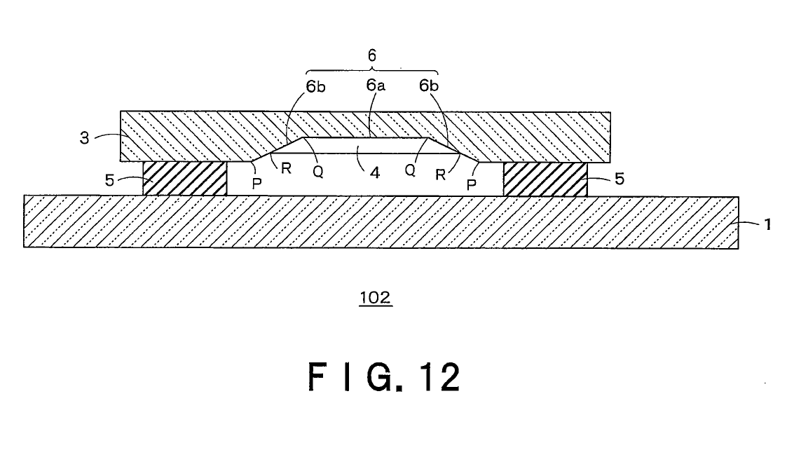

FIG. 11 is a cross-sectional view of the organic EL device 102, taken along the line C-C′ of FIG. 10. As shown in FIG. 11, the drying agent 4 is not provided above the organic EL elements 2. FIG. 12 is a cross-sectional view of the organic EL device 102, taken along the line D-D′ of FIG. 10. As shown in FIG. 12, in the areas that are located outside the organic EL elements 2 in the longitudinal direction and do not have the organic EL elements 2 formed therein, the drying agent 4 is applied to the bottom portion 6a and at least a part of the sidewall portions 6b of the concave portion 6.

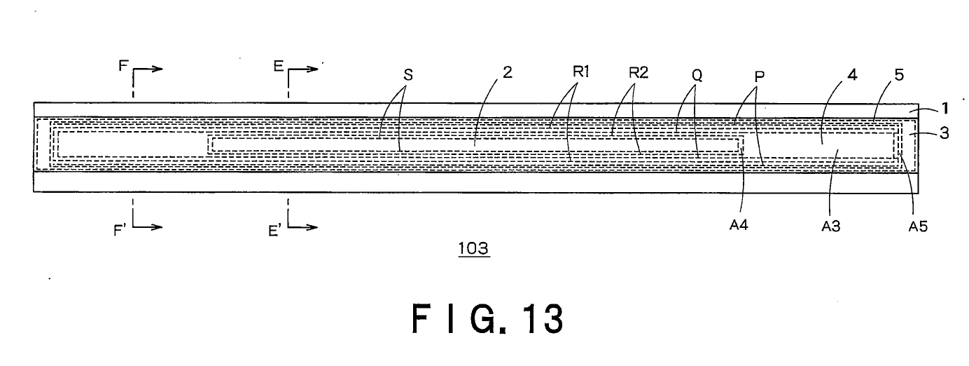

FIG. 13 is a plan view of an organic EL device 103 as a modification of the second embodiment. The organic EL device 103 of FIG. 13 is similar to the organic EL device 102 of FIG. 10 in that the drying agent 4 is not applied to the concave portion 6 located above the organic EL elements 2. In the concave portion 6 formed in the second substrate 3 of the organic EL device 103, the drying agent 4 is applied not only to the concave portion 6 located outside the organic EL elements 2 in the longitudinal direction but also to a part of the sidewall portions 6b and a part of the bottom portion 6a located diagonally above the organic EL elements 2. With this arrangement, the light emitted by the organic EL elements 2 is not shielded by the drying agent 4, and is taken out from the organic EL device 103. Furthermore, the area in which the drying agent 4 is provided can be made larger than that in the organic EL device 102 shown FIGS. 10 through 12.

In the organic EL device 103, “A3” represents the total of areas in which the drying agent 4 is applied inside the adhesive agent 5 (disregarding the areas inside the broken lines R1 and R2 and the areas of the sidewall portions 6b′ in which the drying agent 4 is not provided), “A4” represents the total of areas of the concave portion 6 in which the drying agent 4 is not provided (the area inside the broken line R2), and “A5” represents the area in which the concave portion 6 is not formed, that is, the area obtained by subtracting the areas “A3” and “A4” from the area inside the adhesive agent 5. Those parameters are used for determining the later described upper limit of the thickness “d” of the drying agent 4.

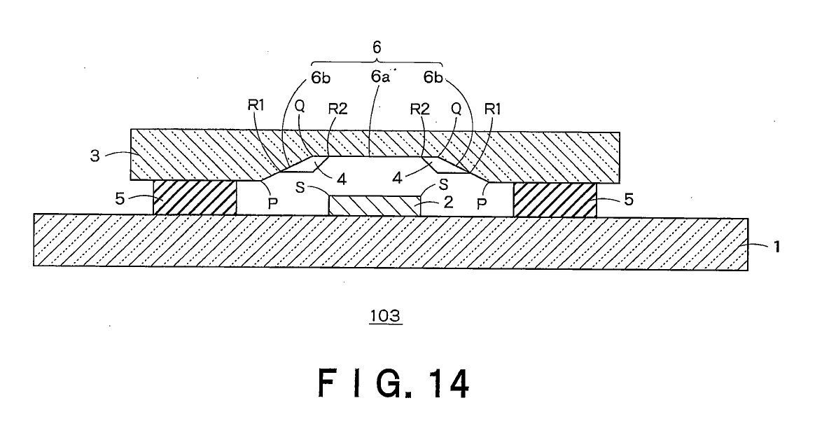

FIG. 14 is a cross-sectional view of the organic EL device 103, taken along the line E-E′ of FIG. 13. As shown in FIG. 14, the drying agent 4 is applied to a part of the sidewall portions 6b and a part of the bottom portion 6a located diagonally above the organic EL elements 2. Note that, because the cross-sectional view taken along the line F-F′ of FIG. 13 is similar to the cross-sectional view of FIG. 12, FIG. 13 is not shown in a drawing.

In the organic EL device 103, a high-viscosity drying agent 4 containing a viscosity modifier is applied in step S2 of FIG. 3. Accordingly, the drying agent 4 does not flow to the bottom portion 6a located immediately above the organic EL elements 2, and can be applied only to a part of the sidewall portions 6b and regions of the bottom portion 6a located near the sidewall portions 6b.

In this embodiment, the upper limit of the thickness “d” of the drying agent 4 is not determined according to the equation (5). The heights “h0”, “h1”, and “H0”, and the pressures “P0” and “P1” are defined in the same manner as in the first embodiment. According to Boyle's law, the following equation (6) is established:

P0*{(H+h0)*A3+(H0+h0)*A4+h0*A5}=P1*{(H+h1)*A3+(H0+h1)*A4+h1*A5} (6)

Here, the pressure “P1” needs to be equal to or lower than atmospheric pressure, 1 atm. Therefore, the following equation (7) is established:

P1≦1 (7)

Based on the above equations (6) and (7) and because the depth of the concave portion 6 is smaller than half the thickness “D” of the second substrate 3, the following equation (8) is established:

(A3+A4+A5)*(h0*P0−h1)/{A3*(1−P0)}−A4*H0/A3≦H<D/2 (8)

Here, the area “A3” is larger than 0, and the pressure “P0” is lower than 1, as in the equation (3). Therefore, the thickness “d” of the drying agent 4 needs to satisfy the following equation (9):

d=H0−H≦H0−(A3+A4+A5)*(h0*P0−h1)/{A1*(1−P0)}−A4*H0/A3 (9)

The amount of the drying agent 4 necessary for absorbing moisture and protecting the organic EL elements 2 is set, and the drying agent 4 is provided so as to satisfy the above equation (9). In this manner, an appropriate amount of the drying agent 4 can be provided so that the moisture in the organic EL devices 102 and 103 can be sufficiently absorbed, and the pressure therein does not become too high.

As described above, in the second embodiment, the drying agent 4 is applied to the sidewall portions 6b of the concave portion 6 formed in the second substrate 3. Accordingly, the organic EL devices 102 and 103 can have small widths. Furthermore, the drying agent 4 is not applied to the region located above the organic EL elements 2. Accordingly, the light emitted by the organic EL elements 2 is not shielded by the drying agent 4 in the organic EL devices 102 and 103 of the top emission type. Thus, this embodiment can be applied to organic EL devices 102 and 103 of both the top emission type and the bottom emission type.

In a case where a transparent drying agent 4 is used, the drying agent 4 may be applied above the organic EL elements 2, as shown in FIGS. 1 and 2, even in an organic EL element of the top emission type.

Each of the above described embodiments is useful particularly in organic EL devices having long and thin shapes for printer heads and the like. More specifically, each of the above described embodiments is useful in organic EL devices in which the short-side length is 1/10 or less of the long-side length determined by the size of paper sheet to be printed.

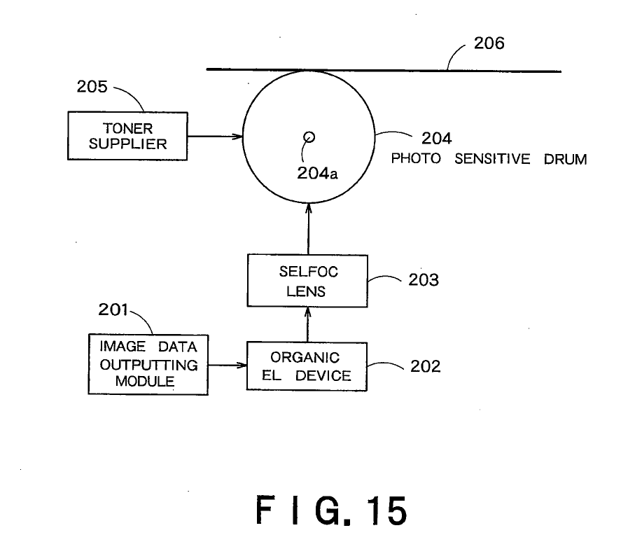

An example of a configuration of a printer will be explained where the organic EL devices according to the above embodiments is used as a printer head. FIG. 15 is a schematic block diagram showing a printer using an organic EL device. The printer has an image data outputting module 201, an organic EL element 202, a Selfoc lens 203, a photosensitive drum 204 and a toner supplier 205. The printer performs printing on a paper 206 as below.

Firstly, the entire surface of the photosensitive drum 204 is uniformly charged. Then, the organic EL device 202 emits light whose pattern depends on an image data (including characters) outputted from the image data outputting module 201. This light is collected by the Selfoc lens 203 and forms an image on the photosensitive drum 204 which rotates around an axis 204a provided perpendicular to the drawing. The photosensitive drum 204 is exposed with a pattern depending on the image data, and exposed parts are discharged. Note that, the photosensitive property of the photosensitive drum 204 is adjusted so that the sensitivity becomes high at a wavelength of the light emitted by the organic EL element 202. Next, toners are supplied by the toner supplier 205 and attach only on the charged parts of the photosensitive drum 204. Then, the paper 206 is pressed on the photosensitive drum 204, and the image depending on the image data is printed on the paper 206 by transcribing the toners attaching on the photosensitive drum 204 into the paper 206.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the inventions.

1. An organic EL device comprising:
a first substrate on which an organic EL element is formed;
a second substrate comprising a first surface facing the first substrate and a second surface on an opposite side from the first surface, a concave portion comprising a bottom portion and a sidewall portion being formed on the first surface;
an adhesive agent surrounding the organic EL element, the adhesive agent is configured to join the first substrate and the second substrate to each other; and
a drying agent applied to at least a part of the bottom portion and the sidewall portion of the concave portion,
wherein a distance “H” between a surface of the drying agent and the first surface of the second substrate is within a range defined by a following equation (1):
(A1+A2)*(h0*P0−h1)/{A1*(1−P0)}≦H<D/2 (1)
where “A1” represents an area of a region where the concave portion is formed, “A2” represents an area obtained by subtracting the area of the region where the concave portion is formed from an area inside the adhesive agent in the second substrate, “h0” and “P0” represent a height of the adhesive agent and a pressure in a surrounding area of the organic EL element before the first substrate and the second substrate are pressurized and joined to each other respectively, “h1” and “P1” represent a height of the adhesive agent and a pressure in the surrounding area of the organic EL element after the first substrate and the second substrate are pressurized and joined to each other respectively, “D” represents a thickness of the second substrate, “A1” is greater than 0, and “P0” is lower than 1.

2. The device of claim 1, wherein a length of a short-side direction of the second substrate is longer than 3.8 mm and equal to or less than 5.8 mm.

3. The device of claim 1, wherein a thickness of the drying agent is equal to or more than 0.11 mm, and the distance “H” is equal to or more than 0.1 mm.

4. The device of claim 1, wherein the drying agent is not applied above the organic EL element, and applied to at least a part of the concave portion located outside the organic EL element in a longitudinal direction.

5. The device of claim 4, wherein the drying agent is applied to at least a part of the sidewall portion diagonally above the organic EL element.

6. The device of claim 4, wherein light emitted by the organic EL element is taken out from a side of the second substrate.

7. A printer comprising:
an organic EL device configured to emit light whose pattern depends on image data;
a photosensitive drum configured to be exposed by the light with the pattern depending on the image data; and
a toner supplier configured to supply the photosensitive drum with a toner,
wherein the organic EL device comprises:
a first substrate on which an organic EL element is formed;
a second substrate comprising a first surface facing the first substrate and a second surface on an opposite side from the first surface, a concave portion comprising a bottom portion and a sidewall portion being formed on the first surface;
an adhesive agent surrounding the organic EL element, the adhesive agent is configured to join the first substrate and the second substrate to each other; and
a drying agent applied to at least a part of the bottom portion and the sidewall portion of the concave portion,
wherein a distance “H” between a surface of the drying agent and the first surface of the second substrate is within a range defined by a following equation (2):
(A1+A2)*(h0*P0−h1)/{A1*(1−P0)}≦H<D/2 (2)
where “A1” represents an area of a region where the concave portion is formed, “A2” represents an area obtained by subtracting the area of the region where the concave portion is formed from an area inside the adhesive agent in the second substrate, “h0” and “P0” represent a height of the adhesive agent and a pressure in a surrounding area of the organic EL element before the first substrate and the second substrate are pressurized and joined to each other respectively, “h1” and “P1” represent a height of the adhesive agent and a pressure in the surrounding area of the organic EL element after the first substrate and the second substrate are pressurized and joined to each other respectively, “D” represents a thickness of the second substrate, “A1” is greater than 0, and “P0” is lower than 1.

8. The printer of claim 7 further comprising:
an image data outputting device configured to supply the organic EL device with the image data; and
a lens configured to collect the light emitted by the organic EL device on the photosensitive drum.

9. The printer of claim 7, wherein a length of a short-side direction of the second substrate is longer than 3.8 mm and equal to or less than 5.8 mm.

10. The printer of claim 7, wherein a thickness of the drying agent is equal to or more than 0.11 mm, and the distance “H” is equal to or more than 0.1 mm.

11. The printer of claim 7, wherein the drying agent is not applied above the organic EL element, and applied to at least a part of the concave portion located outside the organic EL element in a longitudinal direction.

12. The printer of claim 11, wherein the drying agent is applied to at least a part of the sidewall portion diagonally above the organic EL element.

13. The printer of claim 11, wherein light emitted by the organic EL element is taken out from a side of the second substrate.

14. A method of manufacturing an organic EL device that comprises a first substrate on which an organic EL element is formed and a second substrate comprising a first surface facing the first substrate and a second surface on an opposite side from the first surface, comprising;
forming a concave portion comprising a bottom portion and a sidewall portion on the first surface of the second substrate;
applying a fluid drying agent dissolved in a solvent to at least a part of the bottom portion and the sidewall portion;
performing first baking on the second substrate to which the drying agent is applied to remove the solvent, whereby curing the drying agent;
performing O₂ ashing on the second substrate after the first baking to remove an adherent matter volatilized from the drying agent and remaining on the second substrate;
performing second baking on the second substrate after the O₂ ashing to remove oxygen and moisture generated through the O₂ ashing from the second substrate;
arranging an adhesive agent around the organic EL element to bond the first substrate and the second substrate to each other; and
pressurizing the adhesive agent to join the first substrate and the second substrate to each other.

15. The method of claim 14, wherein upon applying the fluid drying agent, a distance “H” between a surface of the drying agent and the first surface of the second substrate is within a range defined by a following equation (3):
(A1+A2)*(h0*P0−h1)/{A1*(1−P0)}≦H<D/2 (3)
where “A1” represents an area of a region where the concave portion is formed, “A2” represents an area obtained by subtracting the area of the region where the concave portion is formed from an area inside the adhesive agent in the second substrate, “h0” and “P0” represent a height of the adhesive agent and a pressure in a surrounding area of the organic EL element before the first substrate and the second substrate are pressurized and joined to each other respectively, “h1” and “P1” represent a height of the adhesive agent and a pressure in the surrounding area of the organic EL element after the first substrate and the second substrate are pressurized and joined to each other respectively, “D” represents a thickness of the second substrate, “A1” is greater than 0, and “P0” is lower than 1.

16. The method of claim 15, wherein a length of a short-side direction of the second substrate is longer than 3.8 mm and equal to or less than 5.8 mm.

17. The method of claim 15, wherein a thickness of the drying agent is equal to or more than 0.11 mm, and the distance “H” is equal to or more than 0.1 mm.

18. A method of manufacturing an organic EL device that comprises a first substrate on which an organic EL element is formed and a second substrate comprising a first surface facing the first substrate and a second surface on an opposite side from the first surface, comprising;
forming a concave portion comprising a bottom portion and a sidewall portion on the first surface of the second substrate;
applying a fluid drying agent dissolved in a solvent to at least a part of the bottom portion and the sidewall portion;
performing baking on the second substrate to which the drying agent is applied to remove the solvent, whereby curing the drying agent;
performing O₂ ashing on the second substrate after the baking to remove an adherent matter volatilized from the drying agent and remaining on the second substrate;
arranging an adhesive agent around the organic EL element to bond the first substrate and the second substrate to each other; and
pressurizing the adhesive agent to join the first substrate and the second substrate to each other.

19. The method of claim 18, wherein upon applying the fluid drying agent, a distance “H” between a surface of the drying agent and the first surface of the second substrate is within a range defined by a following equation (4):
(A1+A2)*(h0*P0−h1)/{A1*(1−P0)}≦H<D/2 (4)
where “A1” represents an area of a region where the concave portion is formed, “A2” represents an area obtained by subtracting the area of the region where the concave portion is formed from an area inside the adhesive agent in the second substrate, “h0” and “P0” represent a height of the adhesive agent and a pressure in a surrounding area of the organic EL element before the first substrate and the second substrate are pressurized and joined to each other respectively, “h1” and “P1” represent a height of the adhesive agent and a pressure in the surrounding area of the organic EL element after the first substrate and the second substrate are pressurized and joined to each other respectively, “D” represents a thickness of the second substrate, “A1” is greater than 0, and “P0” is lower than 1.

20. The method of claim 18, wherein a length of a short-side direction of the second substrate is longer than 3.8 mm and equal to or less than 5.8 mm.
